(19) United States
(12) Patent Application Publication
(10) Pub. No.: US 2014/0333563 A1
(43) Pub. Date: Nov. 13, 2014

(54) DISPLAY DEVICE AND DISPLAY SYSTEM

(71) Applicants: Kohji Saitoh, Osaka (JP); Akizumi Fujioka, Osaka (JP); Masami Ozaki, Osaka (JP); Toshihiro Yanagi, Osaka (JP)

(72) Inventors: Kohji Saitoh, Osaka (JP); Akizumi Fujioka, Osaka (JP); Masami Ozaki, Osaka (JP); Toshihiro Yanagi, Osaka (JP)

(73) Assignee: SHARP KABUSHIKI KAISHA, Osaka (JP)

(21) Appl. No.: 14/345,598

(22) PCT Filed: Sep. 14, 2012
(86) PCT No.: PCT/JP2012/073724

§ 371 Date: Mar. 18, 2014

(30) Foreign Application Priority Data
Sep. 21, 2011 (JP) 2011-206357

(51) Int. Cl. H01L 27/12; G09G 3/36; G06F 3/041

(52) U.S. Cl. CPC H01L 27/124; G06F 3/0412; G09G 3/3648; H01L 27/1225; G09G 2354/00
USPC 345/173

(57) ABSTRACT

A display device (110) is provided with a detection controller (122) that controls a detection device (130) such that detection is carried out within a horizontal blanking period for a display panel (112). An oxide semiconductor is used in the semiconductor layer for a TFT for each of the plurality of pixels provided in the display panel (112).

### TECHNICAL FIELD

The present invention relates to a display device and display system.

### BACKGROUND ART

Recently, display devices with a thin profile, light weight, and low power consumption such as liquid crystal display devices are widely used. Such display devices are mainly used for mobile phones, smartphones, PDAs (personal digital assistants), electronic books, laptop personal computers, and the like, for example. Also, electronic paper, which is an even thinner display device, is expected to be developed and put in practical use rapidly in the coming years.

Among such display devices, touch panels are widely used as the input device for inputting various information. Generally, touch panels are provided so as to cover the surface of the display panel. Thus, touch panels are susceptible to receiving noise from the display panel, and a resulting issue is that the detection accuracy of the touch panel could not be improved sufficiently.

Techniques that aim to solve such an issue with respect to display devices have been considered.

For example, Patent Document 1 below discloses a display system including a touch controller that generates touch data in synchronization with timing data from a host controller or with timing data from a display driver circuit. According to this display system, by controlling the display system such that touch data is generated during periods in which the voltage provided on the display panel is stable, the effect of noise during touch screen operation can be reduced.

### RELATED ART DOCUMENT

### Patent Document

Patent Document 1: Japanese Patent Application Laid-Open Publication, “Japanese Patent Application Laid-Open Publication No. 2010-108501 (Published on May 13, 2010)”

### SUMMARY OF THE INVENTION

### Problems to be Solved by the Invention

In recent display devices, the display drive time has been lengthened as the resolution has increased. In the technique disclosed in Patent Document 1, touch data cannot be generated during the display drive time (that is, the period during which the voltage provided on the display panel is stable), and thus, it is not possible to ensure a sufficient amount of time to perform touch screen operations, which results in an inability to improve the detection accuracy of the touch screen to a sufficient degree.

The present invention takes into account the aforementioned problem, and an object thereof is to provide a display device and display system in which a detection time by a detection device is lengthened while mitigating effects resulting from the operation of the detection device.

### Means for Solving the Problems

In order to solve the above-mentioned problems, a display device according to one aspect of the present invention includes: a display panel having a plurality of gate signal lines, a plurality of source signal lines arranged so as to intersect the plurality of gate signal lines, and a plurality of pixels disposed at intersections between the plurality of gate signal lines and the plurality of source signal lines; and a detection controller that controls a detection device such that the detection device performs detection during a horizontal blanking period of the display panel, wherein a semiconductor layer of a thin film transistor in each of the plurality of pixels is made of an oxide semiconductor.

According to this invention, the detection device is controlled such that detection is performed during a horizontal blanking period in the display panel, and thus, the effect of noise and the like from the display panel on the operation of the detection device can be mitigated. In particular, by using TFTs using an oxide semiconductor, which has a relatively high electron mobility, as the TFTs of the respective plurality of pixels, the electron mobility when writing the pixel data to the respective pixels is increased, thus shortening the amount of time taken when writing. As a result, it is possible to provide a sufficient horizontal blanking period, which is a period during which the detection device performs detection. Thus, the detection accuracy of the detection device can be increased.

Also, a display device according to one aspect of the present invention includes: a display panel having a plurality of gate signal lines, a plurality of source signal lines arranged so as to intersect the plurality of gate signal lines, and a plurality of pixels disposed at intersections between the plurality of gate signal lines and the plurality of source signal lines; and a detection controller that controls a detection device such that the detection device performs detection during a horizontal blanking period of the display panel, wherein at least either of the plurality of gate signal lines or the plurality of source signal lines is made of copper.

According to this invention, the detection device is controlled so as to perform detection during the horizontal blanking period of the display panel, and thus, it is possible to mitigate the effect of noise and the like from the display panel on the operation of the detection device. In particular, by using copper, which has a relatively low wiring resistance, for the plurality of source signal lines, it is possible to shorten the delay period when writing the pixel data to the respective pixels, and thus, it is possible to shorten the writing period. Also, by using copper, which has a relatively low wiring resistance, for the plurality of gate signal lines, it is possible to shorten the delay period when applying an ON voltage to each gate signal line and thereby selectively scanning it, and thus, it is possible to shorten the amount of time taken for selective scanning. As a result, it is possible to provide a sufficient horizontal blanking period, which is a period during which the detection device performs detection. Thus, the detection accuracy of the detection device can be increased.

A display system according to one aspect of the present invention includes a display device and a detection device with a detection portion.

According to this invention, it is possible to provide a display system that can provide effects similar to the display device.

### Effects of the Invention

According to the display device and display system of the present invention, the detection device is controlled such that detection is performed during a horizontal blanking period in the display panel, and thus, the effect of noise and the like on the display panel due to the operation of the detection device can be mitigated. In particular, according to the display device and display system of the present invention, the electron mobility in the display panel during display driving can be increased while the delay period can be decreased, and thus, it is possible to shorten the drive period of the display. As a result, it is possible to provide a sufficient horizontal blanking period, which is a period during which the detection device performs detection. Thus, the detection accuracy of the detection device can be increased.

### BRIEF DESCRIPTION OF THE DRAWINGS

FIG. 1 shows an overall configuration of a display system of Embodiment 1.

FIG. 2 shows a configuration of pixels included in a display panel.

FIG. 3 shows characteristics of various types of TFTs.

FIG. 4 shows a pseudo-equivalent circuit of each source signal line S.

FIG. 5 shows a pseudo-equivalent circuit of each gate signal line G.

FIG. 6 shows an overall configuration of a display system of Embodiment 2.

FIG. 7 is a schematic view showing a configuration of a display panel and a detection portion of Embodiment 4.

FIG. 8 is a schematic view showing a configuration of a display panel and a detection portion of Embodiment 5.

### DETAILED DESCRIPTION OF EMBODIMENTS

Embodiments of the present invention will be explained below with reference to drawings.

### Embodiment 1

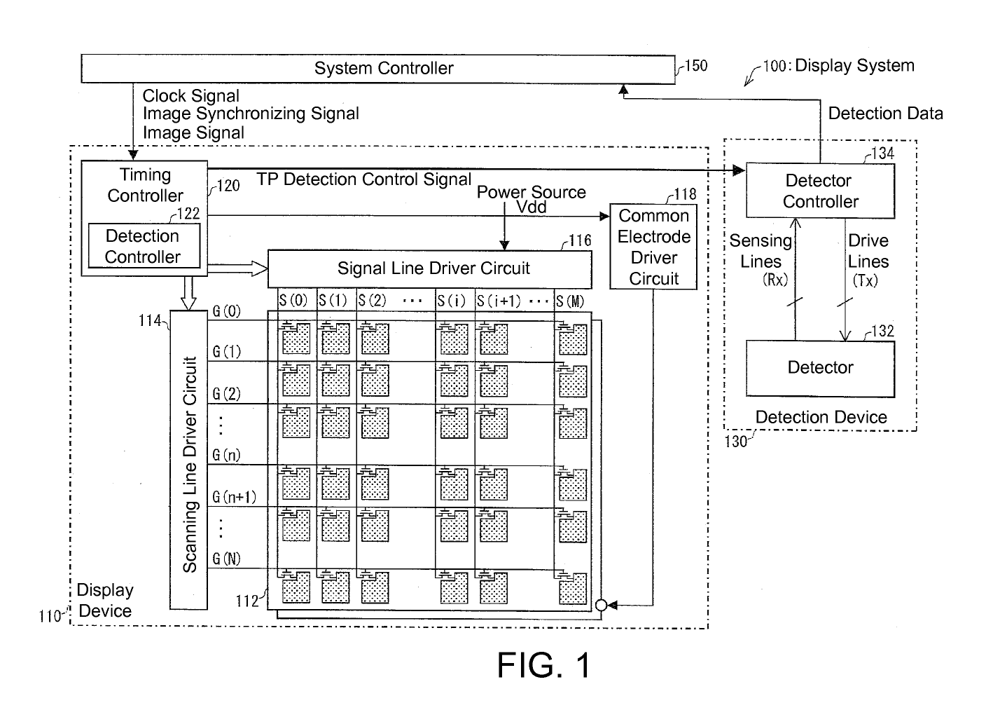

First, Embodiment 1 of the present invention will be explained with reference to FIGS. 1 to 5.

(Configuration of Display System)

First, a configuration example of a display system 100 of Embodiment 1 will be described with reference to FIG. 1. FIG. 1 shows an overall configuration of the display system 100 of Embodiment 1.

As shown in FIG. 1, the display system 100 includes a display device 110, a detection device 130, and a system controller 150.

The display system 100 is included in mobile information devices (hereinafter referred to as the main device) such as mobile phones, smartphones, PDAs (personal digital assistants), and electronic books, for example, and has the function of inputting and displaying various data in the main device.

The detection device 130 is for inputting various data to the main device. The display device 110 is for displaying various data from the main device.

In the present embodiment, an active matrix liquid crystal display device is used as the display device 110. The display device 110 includes an active matrix liquid crystal display panel. In the present embodiment, a touch panel unit is used as the detection device 130. The touch panel unit has a touch panel provided to cover the front surface of the liquid crystal display panel.

The system controller 150 is for controlling the display device 110 and the detection device 130. The system controller 150 receives detection data based on an input operation from the detection device 130, and issues commands to the main device so as to perform input processes based on the received detection data, for example. Also, the system controller 150, upon receiving a command by the main device to display an image, sends an image signal and an image synchronizing signal based on this image to the display device 110, thus displaying this image in the display device 110.

(Configuration of Display Device)

A specific configuration of the display device 110 will be explained. The display device 110 includes a display panel 112, a scanning line driver circuit 114, a signal line driver circuit 116, a common electrode driver circuit 118, and a timing controller 120.

(Display Panel)

The display panel 112 includes a plurality of pixels, a plurality of gate signal lines G and a plurality of source signal lines S.

The plurality of pixels are arranged in a so-called grid pattern including a plurality of columns of pixels and a plurality of rows of pixels.

The plurality of gate signal lines G are aligned in a pixel column direction (direction along the columns of pixels). The respective plurality of gate signal lines G are electrically connected to the respective pixels in a corresponding row of pixels among the plurality of rows of pixels.

The plurality of source signal lines S are aligned in a pixel row direction (direction along the rows of pixels), all of which intersect with the respective plurality of gate signal lines G. The respective plurality of source signal lines S are electrically connected to the respective pixels in a corresponding column of pixels among the plurality of columns of pixels.

In the example shown in FIG. 1, the plurality of pixels are arranged in M columns and N rows in the display panel 112. Based on this, the display panel 112 includes an M number of source signal lines S and an N number of gate signal lines G.

(Scanning Line Driver Circuit)

The scanning line driver circuit 114 sequentially selects the respective plurality of gate signal lines G and scans them. Specifically, the scanning line driver circuit 114 sequentially selects the plurality of gate signal lines G, and applies an ON voltage to a selected gate signal line G in order to switch ON switching elements (TFTs) included in each pixel on this gate signal line G.

(Signal Line Driver Circuit)

While the gate signal line G is selected, the signal line driver circuit 116 sends source signals based on image data through corresponding source signal lines S to the respective pixels on this gate signal line G. Specifically, the signal line driver circuit 116 calculates voltages to be outputted to the respective pixels on the selected gate signal line G based on an image signal inputted from the timing controller 120, and outputs these voltages to the respective source signal lines S through source output amplifiers. As a result, the source signals are sent to the respective pixels on the selected gate signal line G, and the source signals (that is, the image data) are written to these pixels.

(Common Electrode Driver Circuit)

The common electrode driver circuit 118 applies a prescribed common voltage for driving a common electrode to the common electrode provided for the respective plurality of pixels.

(Timing Controller)

Clock signals, image synchronizing signals, and image signals are inputted from the system controller 150 to the timing controller 120. The timing controller 120 outputs various control signals to the various driver circuits in order to operate the various driver circuits in synchronization with each other.

The timing controller 120 sends a gate start pulse signal, a gate clock signal GCK and a gate output control signal GOE to the scanning line driver circuit 114, for example. The scanning line driver circuit 114 starts scanning the plurality of gate signal lines G when it receives the gate start pulse signal. The scanning line driver circuit 114 sequentially applies the ON voltage to the respective gate signal lines G based on the gate clock signal GCK and the gate output control signal GOE.

The timing controller 120 also outputs a source start pulse signal, a source latch strobe signal, a source clock signal, and image signals to the signal line driver circuit 116. Based on the source start pulse signal, the signal line driver circuit 116 stores the image data for the respective pixels in a register in accordance with the source clock signal, and sends the source signal to the respective source signal lines S based on image data in accordance with the source latch strobe signal that follows.

(Configuration of Detection Device)

Here, a specific configuration of the detection device 130 will be explained. The detection device 130 includes a detector (detection portion) 132 and a detector controller 134. The detector 132 is provided close to the display surface of the display panel 112 of the display device 110, is driven by the detector controller 134, and detects direct or indirect signals inputted to the detector 132.

The detector controller 134 drives the detector 132 and detects the position of the direct or indirect signal inputted to the detector 132. The detector controller 134 then sends this detection data based on the detected position to the system controller 150. The system controller 150 can specify a position of input operation on the detector 132 based on this detection data.

A capacitive touch panel is used for the detector 132, for example. When the input operation is performed on a position on the capacitive touch panel, a capacitance is formed in that position causing a change in current due to the capacitance, which allows the input operation position to be detected.

The capacitive touch panel has a plurality of drive lines (Tx) and a plurality of sensing lines (Rx) arranged in a grid pattern in the detection device 130 of the present embodiment, for example.

Based on this, the detector controller 134 sequentially inputs a pulse waveform to the respective drive lines (Tx) and the change in the pulse waveform due to the capacitance is detected by the corresponding sensing line (Rx).

The detector controller 134 detects a position of input operation on the detector 132 based on this change (analog data), and generates detection data (digital data) of this position, and conducts prescribed processes on this detection data such as noise removal, and then, the detection data is sent to the system controller 150. The system controller 150 can specify a position of input operation on the detector 132 based on this detection data.

Besides this, a touch panel that specifies a position of input operation on the touch panel based on respective values of weak currents flowing from the four corners of the touch panel through the capacitance can be used as the capacitive touch panel.

(Timing Control for Detection Device Performing Detection)

An additional function of the timing controller 120 of the display device 110 will be explained. The timing controller 120 of the present embodiment has a detection controller (detection control portion) 122. The detection controller 122 controls the timing by which the detection device 130 performs the detection. In particular, the detection controller 122 of the present embodiment controls the detection device 130 such that the detection device 130 performs the detection during each horizontal blanking period of the display panel 112 (that is, the period from when the scanning of a certain gate signal line G ends to when the scanning of the next gate signal line G begins).

Specifically, the timing controller 120 sends a TP detection control signal to the detector controller 134 of the detection device 130 when the display panel 112 enters a horizontal blanking period. The TP detection control signal is a control signal for controlling the timing by which the detection device 130 performs detection.

The detector controller 134 starts the detection when it receives this TP detection control signal. As a result, the detection device 130 can perform detection during the horizontal blanking period of the display panel 112.

It is preferable that the detection device 130 also end the detection during the horizontal blanking period of the display panel 112. There are various ways of implementing this, but one method is to specify in advance the number of detections or the time of the detection such that the detection of the display panel 112 ends during the horizontal blanking period, for example.

As another example, the timing controller 120 may continuously send TP detection control signals to the detection device 130 during the horizontal blanking period, the detection device 130 performing the detection until the TP detection control signal stops.

Alternatively, the timing controller 120 may additionally send the TP detection control signal after the horizontal blanking period, the detection device 130 performing detection until this TP detection control signal is received.

(Configuration of Pixels)

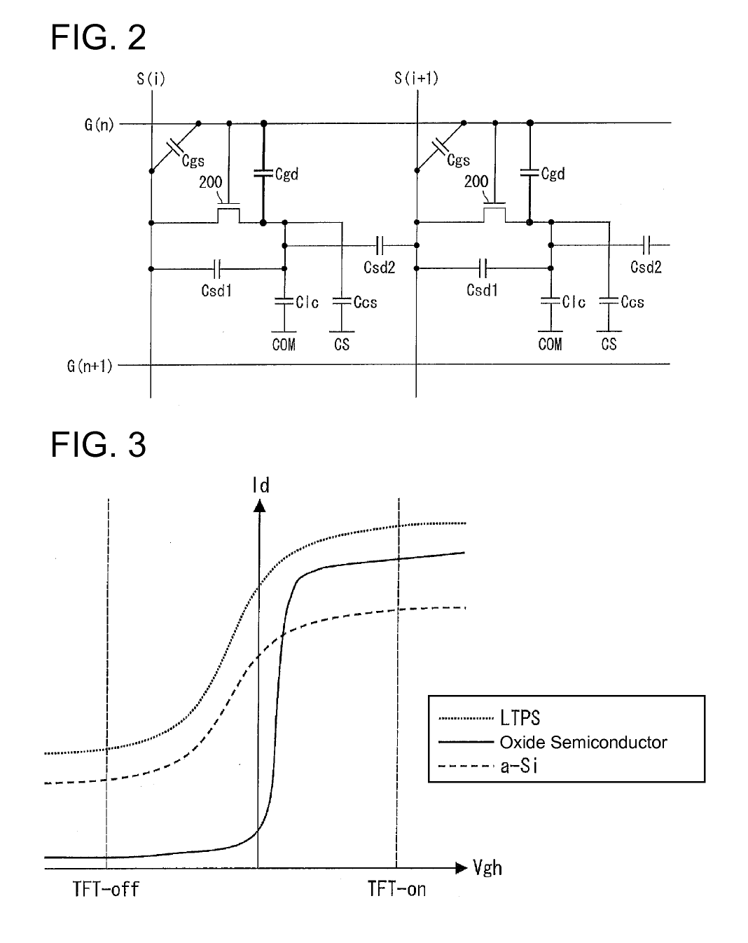

Next, a configuration of pixels included in the display panel 112 will be below. FIG. 2 shows a configuration of pixels included in the display panel 112. FIG. 2 shows a configuration of two pixels (pixel (i, n) and pixel (i+1, n)) among the plurality of pixels included in the display panel 112. The pixel (i, n) refers to a pixel connected to the source signal line S(i) and the gate signal line G(n). The pixel (i+1, n) refers to the pixel connected to the source signal line S(i+1) and the gate signal line G(n). Other pixels included in the display panel 112 have a configuration similar to the above-mentioned pixels.

As shown in FIG. 2, the pixels include TFTs 200 as switching elements. In the display device 110 of Embodiment 1, TFTs having a so-called oxide semiconductor in the semiconductor layer thereof are used as the TFTs 200. IGZO (InGaZnOx), for example, is included among the oxide semiconductors.

The gate electrode of the TFT 200 is connected to a corresponding gate signal line G. The source electrode of the TFT 200 is connected to a corresponding source signal line S. The drain electrode of the TFT 200 is connected to a liquid crystal capacitance Clc and a storage capacitance Ccs.

When pixel data is to be written to this pixel, first, an ON voltage is supplied from the gate signal line G to the gate electrode of the TFT 200. As a result, the TFT 200 is switched ON.

When the TFT 200 is ON, a source signal is supplied from a corresponding source signal line S, and this source signal is supplied from the drain electrode of the TFT 200 to the pixel electrode of the liquid crystal capacitance Clc and the storage capacitance Ccs.

By having the source signal be supplied to the pixel electrode of the liquid crystal capacitance Clc in this manner, the orientation direction of the liquid crystal having an electric field between the pixel electrode and a common electrode of the liquid crystal capacitance Clc changes depending on the difference between the voltage level of the supplied source signal and the voltage level of the voltage applied to the common electrode, and an image is displayed based on this difference.

Also, by having a source signal be supplied to the storage capacitance Ccs, a charge based on the voltage of the source signal is stored in the storage capacitance Ccs. Based on the charge stored in the storage capacitance Ccs, the pixel can maintain a state in which the image is displayed for a certain period of time.

As shown in FIG. 2, in each pixel a parasitic capacitance Cgs and a parasitic capacitance Cgd are formed. The parasitic capacitance Cgs is formed at the intersection between the source signal line S and the gate signal line G, which are metal layers. The parasitic capacitance Cgd is formed between the gate signal line G and the drain electrode.

In each pixel a parasitic capacitance Csd1 and a parasitic capacitance Csd2 are formed. The parasitic capacitance Csd1 is formed between the gate signal line G and the drain electrode. The parasitic capacitance Csd2 is formed between an adjacent gate signal line G and the drain electrode.

When focusing on a certain gate signal line G, a load capacitance Cg in relation to this gate signal line G is the sum of the parasitic capacitance Cgs and the parasitic capacitance Cgd of the pixel connected to this gate signal line G. That is, the load capacitance Cg can be determined based on Formula (1) below.

Cg≈(Cgs+Cgd)×number of source signal lines S (1)

On the other hand, when focusing on a certain source signal line S, a load capacitance Cs in relation to this source signal line S is the sum of the parasitic capacitance Cgs, the parasitic capacitance Cgd1, and the parasitic capacitance Csd2 of the pixel connected to this source signal line S. That is, the load capacitance Cs can be determined based on Formula (2) below.

Cs≈(Cgs+Csd1+Csd2)×number of gate signal lines G (2)

In other words, the load capacitance Cs of the source signal lines S and the load capacitance Cg of the gate signal line G increase based on the increase in the number of pixels due to increasing resolution.

(TFT Characteristics)

FIG. 3 shows characteristics of various types of TFTs. FIG. 3 shows respective characteristics of a TFT using an oxide semiconductor, a TFT using a-Si (amorphous silicon), and a TFT using LTPS (low temperature polysilicon).

In FIG. 3, the horizontal axis (Vgh) shows a value of an ON voltage supplied to the gate of each TFT, and the vertical axis (Id) shows the amount of current flowing between the source and the drain of each TFT.

In particular, the period shown in the drawing as “TFT-on” indicates a period during which the TFT is ON based on the value of the ON voltage, and the period shown in the drawings as “TFT-off' indicates a period during which the TFT is OFF based on the value of the ON voltage.

As shown in FIG. 3, the TFT using the oxide semiconductor has a higher current (electron mobility) in the ON state than the TFT using a-Si.

Although omitted from the drawings, specifically, the TFT using a-Si has an Id current during the TFT-on time of 1 μA, whereas the TFT using the oxide semiconductor has an Id current during the TFT-on time of 20-50 μA.

Thus, the TFT using the oxide semiconductor has an electron mobility during the ON state of approximately 20 to 50 times that of the TFT using a-Si, and thus, has excellent ON characteristics.

Also, as shown in FIG. 3, the TFT using the oxide semiconductor has a lower current (leakage current) during the OFF state than the TFT using a-Si or the TFT using LTPS.

Although omitted from the drawings, specifically, the TFT using the a-Si has an Id current of 10 pA during the TFT-off time, whereas the TFT using the oxide semiconductor has an Id current of approximately 0.1 pA during the TFT-off time.

Thus, the leakage current of the TFT using the oxide semiconductor during the off state is 1/100 of that of the TFT using the a-Si, and thus, the TFT using the oxide semiconductor has excellent off characteristics in which almost no leakage current is generated.

(Load on Source Signal Line and Gate Signal Line)

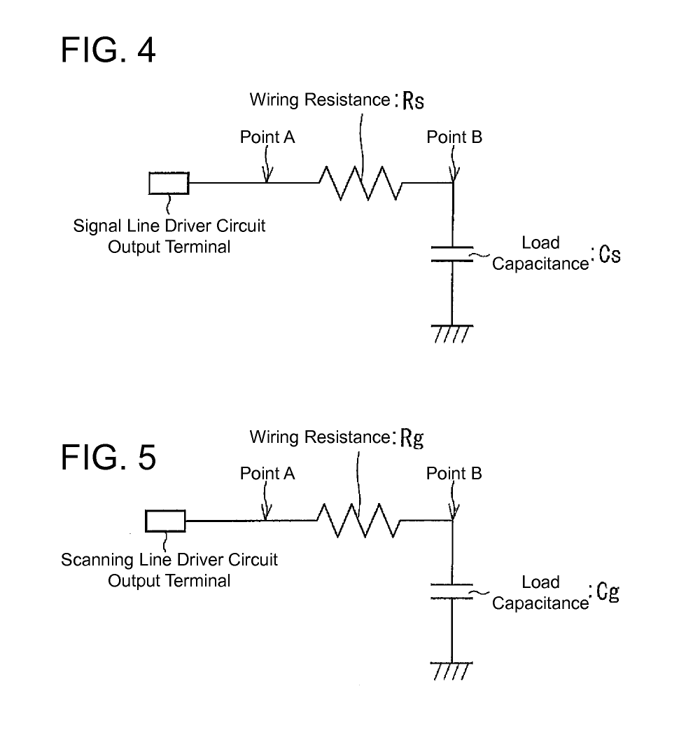

FIG. 4 shows a pseudo-equivalent circuit of each source signal line S. FIG. 5 shows a pseudo-equivalent circuit of each gate signal line G.

As shown in FIG. 4, the pseudo-equivalent circuit of each source signal line S includes a wiring resistance Rs and a load capacitance Cs.

As shown in FIG. 5, the pseudo-equivalent circuit of each gate signal line G includes a wiring resistance Rg and a load capacitance Cg.

A time constant τS indicating the delay period in the source signal line S (the time necessary in order for the voltage at point B to reach a prescribed level (63.2% of the voltage level, for example) after the voltage rises at point A in the pseudo-equivalent circuit shown in FIG. 4) is determined based on Formula (3) below.

τs=Cs×Rs (3)

Also, a time constant τg indicating the delay period in the gate signal line G (the time necessary in order for the voltage at point B to reach a prescribed level (63.2% of the voltage level, for example) after the voltage rises at point A in the pseudo-equivalent circuit shown in FIG. 5) is determined based on Formula (4) below.

τg=Cg×Rg (4)

As can be seen in Formulae (3) and (4), the wiring resistance Rs and Rg and the load capacitance Cs and Cg are both causes for increased delay period in the source signal line S or the gate signal line G. Thus, from the perspective of shortening the writing time of the image data to the respective pixels and shortening the time by which each gate signal line G is selectively scanned, it is preferable that the wiring resistance Rs and Rg and the load capacitance Cs and Cg be as small as possible.

In the display panel 112 of Embodiment 1, a TFT using an oxide semiconductor is used for each pixel, and this TFT has excellent ON characteristics as already described, and thus, it is possible to reduce the size of the TFT of each pixel.

By decreasing the size of the TFT, it is possible to make the parasitic capacitance Cgs in each pixel smaller, and thus, based on Formulae (1) and (2), it is possible to reduce the load capacitance Cs of the source signal lines S and the load capacitance Cg of the gate signal lines G.

Thus, based on Formulae (3) and (4), it is possible to shorten the delay period of the source signal line S and the delay period of the gate signal line G.

(Effects)

As described above, the display device 110 of the present embodiment uses a configuration in which the detection device 130 is controlled such that the detection is performed during the horizontal blanking period of the display panel 112. As a result, the display device 110 of the present embodiment can mitigate the effect of noise and the like from the display panel 112 on the detection by the detection device 130. Thus, the detection accuracy of the detection device 130 can be improved.

In particular, the display device 110 of the present embodiment has TFTs using the oxide semiconductor in each pixel. As a result, in the display device 110 of the present embodiment, the TFTs of the respective pixels have excellent ON characteristics, and thus, the electron mobility when writing pixel data to each pixel increases, which can decrease the amount of time taken for writing.

In other words, in the display device 110 of the present embodiment, the horizontal blanking period of the display panel 112, which is the period during which the detection device 130 performs detection, can be lengthened, and thus, a sufficient amount of time for detection can be ensured for the detection device 130. Thus, the detection accuracy of the detection device 130 can be further improved.

Also, in the display device 110 of the present embodiment, the ON characteristics of the TFTs of the respective pixels are excellent, and thus, the TFTs of the respective pixels can be decreased in size. It is possible to have the TFTs of the respective pixels be approximately ⅕ the size of TFTs in respective pixels using a-Si, for example.

As a result, it is possible to reduce the parasitic capacitance Cgs formed in each pixel, and thus, it is possible to reduce the load capacitance Cs of the source signal line S related to this parasitic capacitance Cgs. Therefore, the time taken to write the pixel data to each pixel can be further shortened. Also, the load capacitance Cg of the gate signal line G related to the parasitic capacitance Cgs can be decreased. Therefore, the amount of time taken to selectively scan each gate signal line G can be further shortened.

Also, due to the small size of the TFTs of the respective pixels, the aperture ratio of the pixels can be increased, which allows an increase in transmittance of the backlight. As a result, because this allows a backlight with low power consumption to be used, or allows the brightness of the backlight to be reduced, a reduction in power consumption can be achieved.

In the display system 100 of the present embodiment, by using TFTs with an oxide semiconductor in each pixel and by lengthening the horizontal blanking period as described above, it is possible to have a horizontal blanking period of 2 μs or greater, which is a very long period of time. This allows a sufficient amount of time for the detection device 130 to perform the detection, and thus, it is possible to improve the detection accuracy of the detection device 130.

### Other Embodiments

Below, other embodiments of the present invention will be described. The display systems 100 described in the other embodiments are similar to the display system 100 described up to here except with respect to points to be described below, and descriptions of the similarities will be omitted. Below, the differences with the display system 100 explained up to here will be described.

### Embodiment 2

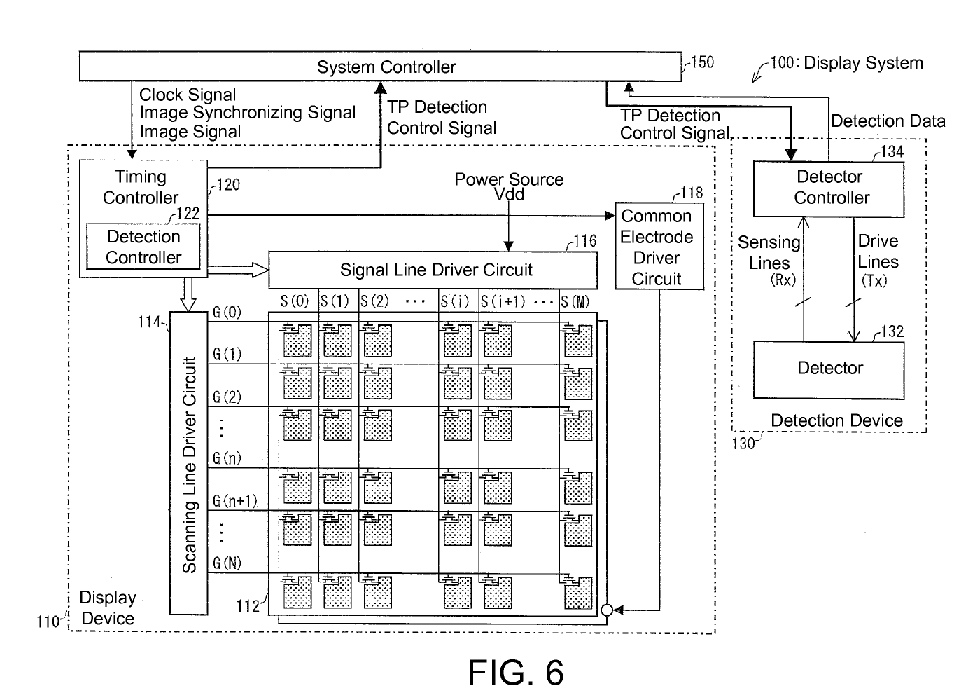

First, Embodiment 2 of the present invention will be explained with reference to FIG. 6.

(Configuration of Display System)

FIG. 6 shows an overall configuration of the display system 100 of Embodiment 2.

As shown in FIG. 6, the display system 100 of Embodiment 2 differs from the display system 100 of Embodiment 1 in that a TP detection control signal outputted by a timing controller 120 is sent to a detector controller 134 through a system controller 150.

When the system controller 150 receives the TP detection control signal from the timing controller 120, it sends a TP detection control signal′ (the TP detection control signal in FIG. 6) based on this TP detection control signal to the detector controller 134. The TP detection control signal′ is a signal in a form readable by the detector controller 134.

In this manner, in the display system 100 of Embodiment 2, by sending the TP detection control signal′ to the detection device 130 through the system controller 150, the detection device 130 can recognize when it is in the horizontal blanking period by having the system controller 150 convert the TP detection control signal to the TP detection control signal′ and send this TP detection control signal′ to the detection device 130, even if the TP detection control signal outputted by the timing controller 120 is not in a form readable by the detector controller 134 or even if the timing controller 120 cannot directly control the detector controller 134 due to the wiring layout in the main device, for example. In this manner, the display system 100 of Embodiment 2 has broad utility, and can be applied with ease to various main devices having different specifications for the display devices or detection devices thereof.

### Embodiment 3

Next, Embodiment 3 of the present invention will be explained.

Material of Source Signal Line and Gate Signal Line

In Embodiment 3, each of a plurality of gate signal lines G and a plurality of source signal lines S included in a display panel 112 is made of copper, which has a lower wiring resistance than aluminum or the like.

As already explained in Formulae (3) and (4) and the like, as the wiring resistance Rs in the source signal lines S becomes greater, the delay period in the source signal lines S becomes longer. Also, as the wiring resistance Rg in the gate signal lines G becomes greater, the delay period in the gate signal lines G becomes longer.

In the display device 110 of Embodiment 3, it is possible to reduce the wiring resistance Rs of the source signal lines S by using copper in the source signal lines S, and thus, it is possible to shorten the delay period in the source signal line S based on the Formula (3). In other words, in the display device 110 of Embodiment 3, it is possible to shorten the writing time for pixel data to the respective pixels.

Similarly, in the display device 110 of Embodiment 3, it is possible to reduce the wiring resistance Rg of the gate signal lines G by using copper in the gate signal lines G, and thus, it is possible to shorten the delay period in the gate signal line G based on the Formula (4). In other words, in the display device 110 of Embodiment 3, it is possible to shorten the time taken to selectively scan each gate signal line G.

In this manner, in the display device 110 of Embodiment 3, the horizontal blanking period of the display panel 112, which is the period during which the detection device 130 performs detection, can be lengthened, and thus, a sufficient amount of time for detection can be ensured for the detection device 130. Thus, the detection accuracy of the detection device 130 can be further improved.

### Embodiment 4

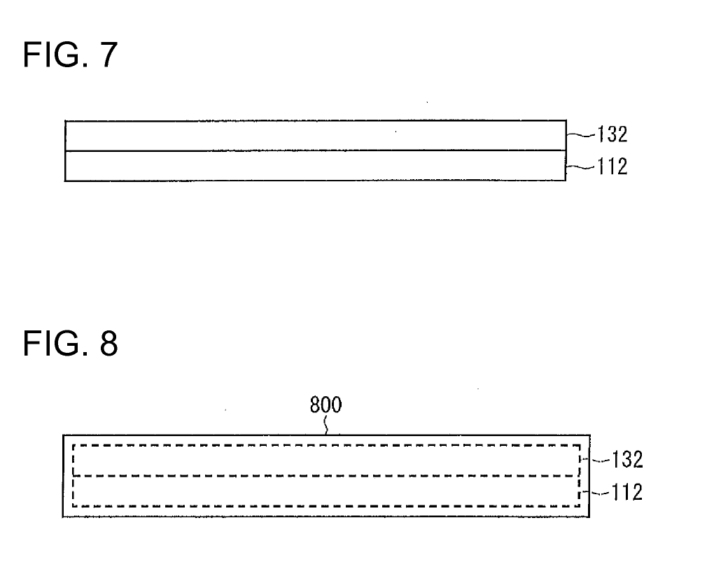

Next, Embodiment 4 of the present invention will be explained with reference to FIG. 7. FIG. 7 is a schematic view showing a configuration of a display panel 112 and a detector 132 of Embodiment 4.

In a display system 100 of the present embodiment, the detector 132 (that is, the touch panel) is stacked onto the surface of the display panel 112, and the surface of the detector 132 and the surface of the display panel 112 that face each other are in close contact with each other. In other words, there is no air layer between these surfaces.

As already described, in the display device 110, there is almost no effect by noise and the like from the display panel 112 on the detection performed by the detection device 130. Thus, it is possible to have the display panel 112 and the detector 132 in close contact with each other as opposed to with a gap therebetween as in conventional devices.

By providing the display system 100 of the present embodiment with such a configuration, it is possible to thin the space between the display panel 112 and detector 132 in the main device provided with the display system 100, and thus, it is possible to thin the main device itself. Also, there is no need for spacers and the like to provide a gap between the display panel 112 and the detector 132, which also allows the manufacturing cost to be reduced.

### Embodiment 5

Next, Embodiment 5 of the present invention will be explained with reference to FIG. 8. FIG. 8 is a schematic view showing a configuration of a display panel 112 and a detector 132 of Embodiment 5.

In a display system 100 of the present embodiment, a display panel 112 and a detector 132 are formed integrally with each other, thus constituting a display/detection unit 800.

Here, “integral” means that the display panel 112 and the detector 132 are housed in the same space within a case or the like of the main device, some of the parts such as substrates are shared, the display panel itself has functions of the detector therein, or the like, for example.

As already described, the display panel 112 has almost no effect on the detection performed by detection device 130. Thus, it is possible to have the display panel 112 and the detector 132 be formed integrally with each other as opposed to being formed separately as in conventional devices.

By providing the display system 100 of the present embodiment with such a configuration, the display/detection unit 800 can be thinned, and during design, manufacturing, distribution, and the like, it is possible to handle the display panel 112 and detector 132 with ease as an integral body.

(Supplementary Description)

Embodiments of the present invention were described above, but the present invention is not limited to the above-mentioned embodiments, and various modifications can be made without departing from the scope of the claims. That is, embodiments obtained by combining techniques modified without departing from the scope of the claims are also included in the technical scope of the present invention.

For example, TFTs using the oxide semiconductor were used in the respective pixels in the embodiments, but the material is not limited thereto, and other TFTs such as TFTs using a-Si, or TFTs using LTPS may be used. Even in such a case, by having at least either of the source signal lines or gate signal lines be made of copper, it is possible to attain the effect of the invention of having a longer detection period for the detection device.

In the embodiments, the detection device 130 (touch panel) was used as an example of a detection device, but the detection device is not limited thereto, and as long as some object to be detected is detected, various types of sensors, antennas, or the like may be used for the detection device. In particular, the application of the present invention is more effective, the more susceptible the detection device is to the effect of noise from the display panel.

In the embodiments, a configuration was used in which the TP detection control signal is sent from the timing controller 120 to the detection device 130, and thus, the detection by the detection device 130 was performed during the horizontal blanking period, but the detection may be performed during the horizontal blanking period by another configuration. For example, a component included in the display device 110 other than the timing controller 120 may send the TP detection control signal to the detection device 130.

<Additional Notes>

In order to solve the above-mentioned problems, a display device according to one aspect of the present invention includes: a display panel having a plurality of gate signal lines, a plurality of source signal lines arranged so as to intersect the plurality of gate signal lines, and a plurality of pixels disposed at intersections between the plurality of gate signal lines and the plurality of source signal lines; and a detection controller that controls a detection device such that the detection device performs detection during a horizontal blanking period of the display panel, in which a semiconductor layer of a thin film transistor in each of the plurality of pixels is made of an oxide semiconductor.

According to this invention, the detection device is controlled such that detection is performed during a horizontal blanking period in the display panel, and thus, the effect of noise and the like from the display panel on the operation of the detection device can be mitigated. In particular, by using TFTs using an oxide semiconductor, which has a relatively high electron mobility, as the TFTs of the respective plurality of pixels, the electron mobility when writing the pixel data to the respective pixels is increased, thus allowing the amount of time taken when writing to be shortened. As a result, it is possible to provide a sufficient horizontal blanking period, which is a period during which the detection device performs detection. Thus, the detection accuracy of the detection device can be increased.

In the display device, it is preferable that the oxide semiconductor be IGZO (InGaZnOx).

According to this invention, by using TFTs using IGZO, which has a higher electron mobility, as the TFTs of the respective plurality of pixels, the electron mobility when writing the pixel data to the respective pixels is increased, thus shortening the amount of time taken when writing. As a result, it is possible to provide a sufficient horizontal blanking period, which is a period during which the detection device performs detection. Thus, the detection accuracy of the detection device can be further improved.

Also, a display device according to one aspect of the present invention includes: a display panel having a plurality of gate signal lines, a plurality of source signal lines arranged so as to intersect the plurality of gate signal lines, and a plurality of pixels disposed at intersections between the plurality of gate signal lines and the plurality of source signal lines; and a detection controller that controls a detection device such that the detection device performs detection during a horizontal blanking period of the display panel, in which at least either of the plurality of gate signal lines or the plurality of source signal lines is made of copper.

According to this invention, the detection device is controlled so as to perform detection during the horizontal blanking period of the display panel, and thus, it is possible to mitigate the effect of noise and the like from the display panel on the operation of the detection device. In particular, by using copper, which has a relatively low wiring resistance, for the plurality of source signal lines, it is possible to shorten the delay period when writing the pixel data to the respective pixels, and thus, it is possible to shorten the writing period. Also, by using copper, which has a relatively low wiring resistance, for the plurality of gate signal lines, it is possible to shorten the delay period when applying an ON voltage to each gate signal line and thereby selectively scanning it, and thus, it is possible to shorten the amount of time taken for selective scanning. As a result, it is possible to provide a sufficient horizontal blanking period, which is a period during which the detection device performs detection. Thus, the detection accuracy of the detection device can be increased.

In the display device, it is preferable that the horizontal blanking period be 2 μs or greater.

According to this configuration, a sufficient amount of time can be ensured for the detection device to perform the detection, and thus, it is possible to further improve the detection accuracy of the detection device.

A display system according to one aspect of the present invention includes a display device and a detection device with a detection portion.

According to this invention, it is possible to provide a display system that can provide effects similar to the display device.

In the display system, it is preferable that the detection portion be a touch panel stacked on a surface of the display panel, and that the surface of the display panel and a surface of the touch panel facing each other be in close contact with each other.

According to this configuration, it is possible to thin the space where the display panel and the detection portion are arranged in a main device having this display system, and thus, it is possible to thin the main device itself. Also, spacers and the like for providing a gap between the display panel and the detection portion are not needed, and thus, the manufacturing cost can also be reduced.

In the display system, it is preferable that the display panel and the detection portion be formed integrally.

According to this configuration, it is possible to handle the display panel and the detection portion integrally and with ease.

### INDUSTRIAL APPLICABILITY

The display device and display system of the present invention can be used in various types of active matrix display devices such as liquid crystal display devices, organic EL display devices, and electronic paper, and in display systems including detection devices such as touch panels in addition to such display devices.

### DESCRIPTION OF REFERENCE CHARACTERS

100 display system

110 display device

112 display panel

114 scanning line driver circuit

116 signal line driver circuit

118 common electrode driver circuit

120 timing controller

122 detection controller (detection control portion)

130 detection device

132 detector (detection portion)

134 detector controller

150 system controller

200 TFT

G gate signal line

S source signal line

1. A display device, comprising:
a display panel having a plurality of gate signal lines, a plurality of source signal lines arranged so as to intersect the plurality of gate signal lines, and a plurality of pixels disposed at intersections between the plurality of gate signal lines and the plurality of source signal lines; and
a detection controller that controls a detection device such that said detection device performs detection during a horizontal retrace period of the display panel,
wherein a semiconductor layer of a thin film transistor in each of the plurality of pixels is made of an oxide semiconductor.

2. The display device according to claim 1, wherein the oxide semiconductor is indium gallium zinc oxide.

3. A display device, comprising:
a display panel having a plurality of gate signal lines, a plurality of source signal lines arranged so as to intersect the plurality of gate signal lines, and a plurality of pixels disposed at intersections between the plurality of gate signal lines and the plurality of source signal lines; and
a detection controller that controls a detection device such that said detection device performs detection during a horizontal retrace period of the display panel,
wherein at least either of the plurality of gate signal lines or the plurality of source signal lines is made of copper.

4. The display device according to claim 1, wherein the horizontal retrace period is set to be 2 μs or greater.

5. A display system, comprising:
the display device according to claim 1; and
a detection device having a detection portion.

6. The display system to according to claim 5,
wherein the detection portion is a touch panel stacked on a surface of the display panel, and
wherein the surface of the display panel and a surface of the touch panel facing each other are in close contact with each other.

7. The display system according to claim 5, wherein the display panel and the detection portion are formed integrally.

8. The display device according to claim 3, wherein the horizontal retrace period is set to be 2 μs or greater.

9. A display system, comprising:
the display device according to claim 3; and
a detection device having a detection portion.

10. The display system to according to claim 9,
wherein the detection portion is a touch panel stacked on a surface of the display panel, and
wherein the surface of the display panel and a surface of the touch panel facing each other are in close contact with each other.

11. The display system according to claim 9, wherein the display panel and the detection portion are formed integrally.
